(19) United States
(12) Patent Application Publication
(10) Pub. No.: US 2026/0098893 A1
(43) Pub. Date: Apr. 9, 2026

(54) METHOD FOR INSPECTING SEMICONDUCTOR DEVICE

(71) Applicant: Renesas Electronics Corporation, Tokyo (JP)

(72) Inventor: Takehiro UEDA, Tokyo (JP)

(21) Appl. No.: 19/304,744

(22) Filed: Aug. 20, 2025

(30) Foreign Application Priority Data
Oct. 3, 2024 (JP) 2024-174649

(51) Int. Cl. G01R 31/26; G01R 1/04

(52) U.S. Cl. CPC G01R 31/2642; G01R 1/0408; G01R 31/2644

(57) ABSTRACT

An inspection is performed to a semiconductor device including a source region formed on an upper surface side of a semiconductor substrate, a drain region formed on a lower surface side of the semiconductor substrate, a trench formed on an upper surface, and a gate electrode and a field plate electrode that are formed in the trench. In the inspection, the source electrode and the drain electrode are fixed to a ground potential, an offset voltage is applied to the field plate electrode, and a screening voltage is applied to the gate electrode. Consequently, insulation properties between the source region and the gate electrode and insulation properties between the gate electrode and the field plate electrode are inspected.

### CROSS-REFERENCE TO RELATED APPLICATIONS

The present application claims priority from Japanese Patent Application No. 2024-174649 filed on Oct. 3, 2024, the content of which is hereby incorporated by reference to this application.

### BACKGROUND

The present invention relates to a method for inspecting a semiconductor device, particularly, to an effective technique applicable to a method for inspecting a vertical MOSFET having a trench gate.

There is a disclosed technique listed below.
[Patent Document 1] Japanese Unexamined Patent Application Publication No. 2010-258153

As a low and medium voltage trench gate power MOSFET, an in-trench double-gate type power MOSFET having a field plate electrode under a gate electrode (genuine gate electrode) in a trench has been known. For example, Patent Document 1 discloses a vertical MOSFET in which the gate electrode and a source wiring layer insulated from each other via a gate insulation film are embedded in a trench.

### SUMMARY

As one method for inspecting a semiconductor device having a MOSFET, a Time Dependent Dielectric Breakdown (TDDB) test has been performed. In this inspection, it is conceivable that a small-thickness portion in the gate insulation film is particularly paid attention to and a high voltage is applied to the gate electrode, thereby checking presence or absence of destruction of the gate insulation film. In contrast, in the in-trench double-gate type power MOSFET, a plurality of types of insulation films different from each other in thickness contact with the gate electrode or the field plate electrode. Thus, even when the portion in the small-thickness gate insulation film is particularly paid attention to and the above inspection is performed, a default(s) generated due to the other insulation film different in the thickness may be overlooked. Accordingly, in the semiconductor device having the in-trench double-gate type power MOSFET, there is a problem in which reliability of the plurality of types of insulation films formed in the trench is ensured, thereby increasing the reliability of the semiconductor device.

Other problems and novel features will be apparent from the description of the present specification and the accompanying drawings.

An outline of a representative embodiment among embodiments disclosed in the present application will be briefly explained as follows.

According to a method for inspecting a semiconductor device that is one embodiment, an inspection is performed to a semiconductor device including: a source region formed on an upper surface side of a semiconductor substrate having an upper surface and a lower surface; a drain region formed on a lower surface side of the semiconductor substrate; a trench formed toward the lower surface from the upper surface; and a gate electrode and a field plate electrode that are formed in the trench. In the inspection, the source electrode and the drain electrode are fixed to a ground potential, a first offset voltage is applied to the field plate electrode, and a first screening voltage is applied to the gate electrode. Consequently, insulation properties between the source region and the gate electrode and insulation properties between the gate electrode and the field plate electrode are inspected.

According to the embodiment, the reliability of the semiconductor device can be improved.

### BRIEF DESCRIPTION OF THE DRAWINGS

FIG. 1 is a plane layout showing a semiconductor device that is an embodiment.

FIG. 2 is a cross-sectional view taken along line A-A of FIG. 1.

FIG. 3 is a cross-sectional view showing the semiconductor device that is the embodiment.

FIG. 4 is an equivalent circuit diagram showing the semiconductor device that is the embodiment.

FIG. 5 is a cross-sectional view showing the semiconductor device that is the embodiment.

FIG. 6 is an equivalent circuit diagram showing the semiconductor device that is the embodiment.

FIG. 7 is a cross-sectional view showing the semiconductor device that is the embodiment.

FIG. 8 is a cross-sectional view showing the semiconductor device that is the embodiment.

FIG. 9 is an equivalent circuit diagram showing the semiconductor device that is the embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle, and the number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments of the present invention will be described in detail with reference to the accompanying drawings. Note that components having the same function are denoted by the same reference characters throughout the drawings for describing the embodiments, and the repetitive description thereof will be omitted.

In each plan view (plane layout) used in later explanation, hatchings are denoted to a contact plug for easily understanding the figures.

Here, as a semiconductor device of the present application, a power MOSFET (Metal Oxide Semiconductor Field Effect Transistor, MOS Field Effect Transistor) will be taken as an example. The power MOSFET is a semiconductor device handling a few watts or more of power. The semiconductor device of the present application has a trench gate power MOSFET out of the power MOSFET. The trench gate power MOSFET is an element that has a gate electrode made of polycrystalline silicon film and the like in a trench (comparatively long and thin groove) formed in an upper surface (first main surface) of a semiconductor substrate and in which a channel is formed in a thickness direction of the semiconductor substrate. In this case, an upper surface side of the semiconductor substrate becomes a source, and a lower surface (back surface, second main surface) side becomes a drain.

In addition, the semiconductor device of the present application has an in-trench double-gate type power MOSFET out of the trench gate power MOSFET. The in-trench double-gate type power MOSFET is an element having a field plate electrode below the gate electrode (genuine gate electrode) in the trench. When connected to a source potential, the field plate electrode disperses a sharp potential gradient concentrated in the vicinity of a drain-side end portion of the gate electrode, and keeps an electric filed constant. By keeping the electric field in the vicinity of the field plate electrode constant, a breakdown voltage of the element can be ensured.

Hereinafter, performing an oxide film breakdown test to the semiconductor device having the in-trench double-gate type power MOSFET will be explained. A first test and a second test that are performed here are inspections performed when insulation films respectively contacting with the gate electrode and the field plate electrode have different thicknesses from each other. The first test and the second test are the inspections performed to the different semiconductor devices. In the first test and the second test, the plurality of insulation films are simultaneously inspected by applying a screening voltage and an offset voltage to each electrode so that the electric fields respectively applied to the plurality of insulation films contacting with each of the gate electrode and the field plate electrode are equal to each other. Hereinafter, the oxide film breakdown test (screening test) is simply called a test.

### Embodiment

### Structure of Semiconductor Device

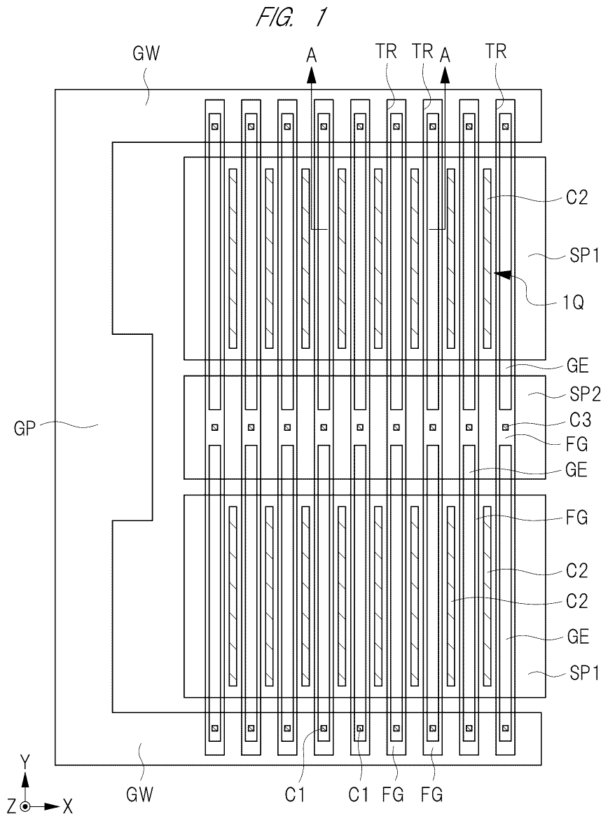

Hereinafter, by using FIG. 1 to FIG. 4, the semiconductor device of the present embodiment will be explained. Here, an X direction and a Y direction are respectively directions along the upper surface of the semiconductor substrate, and are directions orthogonal to each other in plan view. In addition, a Z direction orthogonal to each of the X direction and the Y direction is a height direction (thickness direction, perpendicular direction, vertical direction) perpendicular to the upper surface of the semiconductor substrate. The plan view in the present application means viewing the semiconductor device in the Z direction.

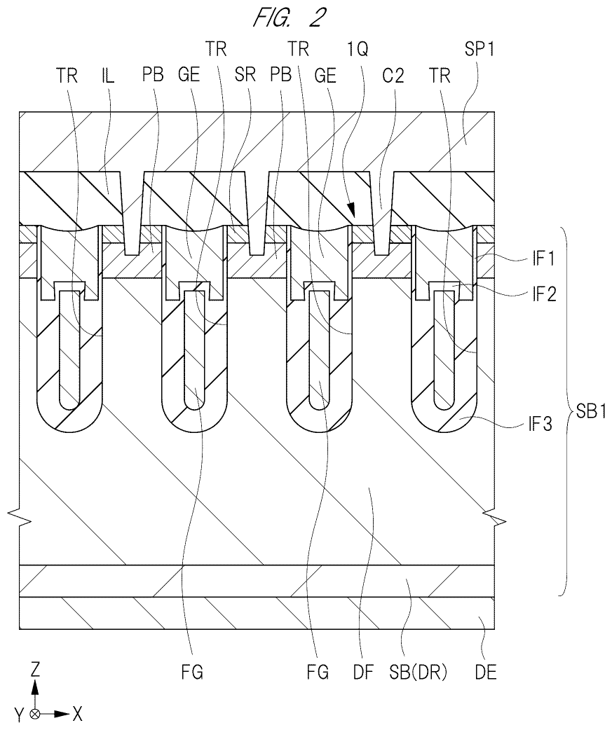

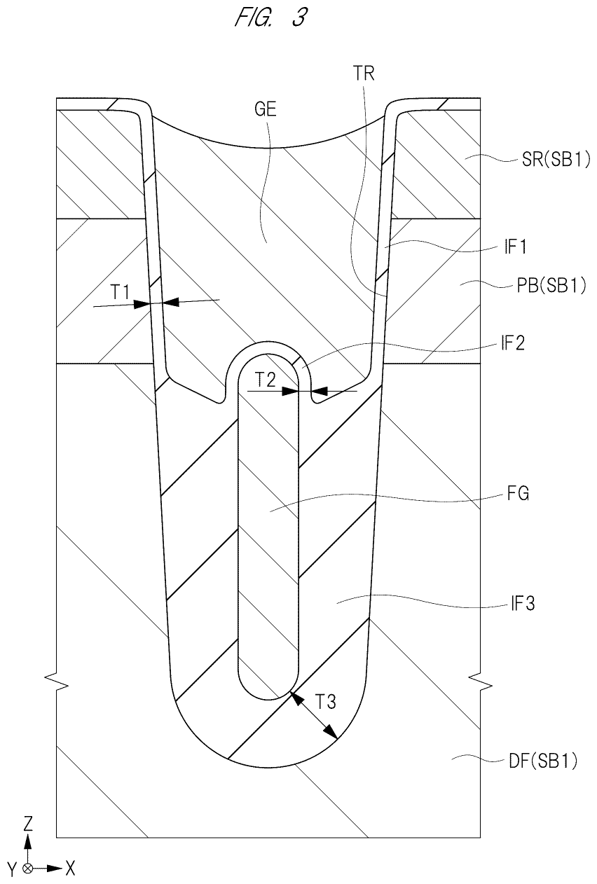

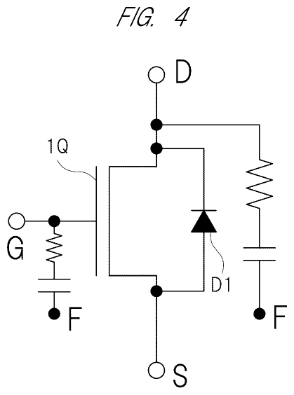

The semiconductor device of the present embodiment has a semiconductor chip having the semiconductor substrate. As shown in FIG. 1, the semiconductor chips are arranged in X direction, and have a plurality of MOSFETs 10 connected to each other in parallel. In FIG. 1, a structure under a wiring formed on the upper surface of the semiconductor substrate is penetrated and shown, and the semiconductor substrate and an insulation film such as an interlayer insulation film and a passivation film on the semiconductor substrate are omitted in the figure. In FIG. 1, an outline of the semiconductor chip is omitted. FIG. 2 shows a cross-sectional view taken along A-A line of FIG. 1. FIG. 3 shows an enlarged cross-sectional view of a structure in the vicinity of the trench shown by FIG. 2. FIG. 4 shows an equivalent circuit diagram of the semiconductor device of the present application. In FIG. 3, the interlayer insulation film on the semiconductor substrate is omitted.

As shown in FIG. 2, a semiconductor substrate SB1 configurating the semiconductor device of the present application has a substrate SB made of, for example, monocrystalline Si (silicon) and the like, and a drift layer DF that is a semiconductor layer formed on the substrate SB by an epitaxial growth method and the like. The semiconductor substrate SB1 has a first main surface, and a second main surface opposite the first main surface. Hereinafter, the first main surface is called an upper surface, and the second main surface is called a lower surface.

The substrate SB configures an n⁺-type drain region DR. That is, the semiconductor substrate SB1 is a lamination substrate configurated by the substrate SB and the drift layer (semiconductor layer) DF, and the semiconductor substrate SB1 has a drain region DR formed up to a predetermined depth from the lower surface. Namely, the drain region DR is formed in the substrate SB between the lower surface of the semiconductor substrate SB1 and the drift layer DF. Although not shown in the figure, the lower surface of the substrate SB is covered with a drain electrode DE including, for example, Au (gold) and the like and the drain region DR is electrically connected to the drain electrode DE. The drift layer DF is an n-type semiconductor layer.

As shown in FIG. 1, on the upper surface of the semiconductor substrate SB1, the plurality of trenches TR extending in the Y direction are formed alongside in the X direction. In the vicinity of the trench TR, a MOSFET 10 is formed.

As shown in FIG. 2 and FIG. 3, a gate electrode (trench gate electrode) GE, and a field plate electrode (trench gate electrode) FG located on a lower surface side of the semiconductor substrate SB1 from the gate electrode GE are formed in the trench TR. Between the semiconductor substrate SB1 and the trench gate GE, an insulation film IF1 that is a gate insulation film is formed. Between the semiconductor substrate SB1 and the field plate electrode FG, an insulation film IF3 that is a gate insulation film is formed. Consequently, the gate electrode GE and the field plate electrode FG electrically from are insulated the semiconductor substrate SB1. Namely, the gate electrode GE and the field plate electrode FG is electrically insulated from the source region SR and the drain region DR, respectively. Between the gate electrode GE and the field plate electrode FG, an insulation film IF2 is formed. Consequently, the gate electrode GE and the field plate electrode FG are electrically insulated from each other.

In this way, a structure in which the two electrodes are formed in the trench is called a double-gate structure (double-gate type) here. A width in a short direction (X direction) of the field plate electrode FG is smaller than a width in a short direction (X direction) of the gate electrode GE on the field plate electrode FG. Therefore, in the X direction, a thickness of the insulation film IF3 between the field plate electrode FG and the semiconductor substrate SB1 is larger than a thickness of the insulation film IF1 between the gate electrode GE and the semiconductor substrate SB1. However, in FIG. 1, the width of the field plate electrode FG is shown largely than its actual width in order to easily understand a shape of the e field plate electrode FG.

Each of the gate electrode GE and the field plate electrode FG is made of, for example, a polycrystalline silicon film. Each of the insulation films IF1, IF2, IF3 is made of, for example, an oxide silicon film.

In the semiconductor substrate SB1, a body layer PB that is a p-type semiconductor layer is formed up to a determined depth from the upper surface (upper surface of the drift layer DF) of the semiconductor substrate SB1 so as to contact with a side surface of the trench TR. Namely, the body layer PB is formed between the upper surface of the semiconductor substrate SB1 and the drift layer DF. A depth of the body layer PB is, for example, shallower than any depth of the trench TR and the gate electrode GE. In other words, the trench TR penetrates through the body layer PB.

In addition, in the semiconductor substrate SB1, the source region SR that is an n+-type semiconductor region (n+ diffusion layer) is formed up to a predetermined depth from the upper surface (upper surface of the drift layer DF, upper surface of the body layer PB) of the semiconductor substrate SB1 so as to contact with the side surface of the trench TR. The source region SR contacts with the upper surface of the semiconductor substrate SB1. A depth of the source region SR is shallower than any depth of the body layer PB and the gate electrode GE. Namely, the source region SR is formed between the upper surface of the semiconductor substrate SB1 and the body layer PB. The lower surface of the source region SR contacts with the body layer PB, and the lower surface of the body layer PB contacts with the drift layer DF. The trench TR penetrates through the source region SR and the body layer PB, and reaches the drift layer DF. Namely, the trench TR penetrates through the source region SR and the body layer PB, and is formed toward the lower surface from the upper surface of the semiconductor substrate SB1 so as to reach the predetermined depth.

The source region SR, the drain region DR, the body layer PB, the gate electrode GE configure an n-type MOSFET 1Q that is the vertical MOSFET.

As shown in FIG. 1 to FIG. 3, on each of the semiconductor substrate SB1, the gate electrode GE, the insulation film IF1, and the field plate electrode FG, a metal film (conductive film, source wiring) and a gate wiring GW that configure each of source pads (source electrodes) SP1, SP2 are formed via the interlayer insulation film IL. The interlayer insulation film IL is mainly made of, for example, an oxide silicon film. The metal film and the gate wiring GW that configure each of the source pads SP1, SP2 are made of, for example, Al (aluminum). The metal film and the gate wiring GW are mutually located at the same height, and are electrically insulated from each other via the interlayer insulation film IL.

A plurality of openings (through holes, contact halls) are formed in the interlayer insulation IL. In those openings, a contact plug (conductive connection portion) integrated with the metal film or the gate wiring GW that configure each of the source pads SP1, SP2 is formed. Hereinafter, the source pads SP1, SP2 strictly indicate portions, which are exposed from an insulation film (not shown) such as a passivation film, in the upper surface of the metal film (source wiring), but such a metal film is called the source pad SP1 or SP2 later.

The trench TR, the gate electrode GE, the field plate electrode FG, a contact plug C2 extend in the Y direction. However, at a center portion of the semiconductor chip in the Y direction, the gate electrode GE in the trench TR is separated into two, and a contact plug C3 is connected to the field plate electrode FG between the two gate electrodes GE adjacent to each other in the Y direction.

One part of the gate wiring GW is formed adjacent an end portion of the source pad SP1 in the Y direction, and extends in the X direction. The other part of the gate wiring GW is adjacent to the source pads SP1, SP2 in the X direction. The gate wiring GW is electrically connected to the gate electrode GE in the trench TR via the contact plug C1. A part of the upper surface of the gate wiring GW configures a gate pad GP, and a gate potential is supplied to the gate electrode GE via the gate pad GP, the gate wiring GW, and the contact plug C1. The contact plug C1 is formed directly on an end portion of the gate electrode GE in the Y direction.

The source pad SP2 is electrically connected to the field plate electrode FG in the trench TR via the contact plug C3. The contact plug C3 is formed directly on the center portion of the field plate electrode FG in the Y direction. In a formation region (power supply portion) vicinity of the contact plug C3, the gate electrode GE is not formed in the trench TR. In other words, in a region in which the contact plug C3 is connected to the upper surface of the field plate electrode FG, the upper surface of the field plate electrode FG is exposed form the gate electrode GE. Namely, in the trench TR in the formation region vicinity of the contact plug C3, the field plate electrode FG is embedded up to an upper end vicinity from a lower end vicinity of the trench TR. A source potential is supplied to the field plate electrode FG via the source pad SP2 and the contact plate C3. Although not shown in the figure, the source pad SP1 and the source pad SP2 are electrically connected to each other via a bonding wire.

The source pad SP1 is electrically connected to the source region SR and the body layer PB via the contact plug C2. The contact plug C2 extends along an extension direction (Y direction) of the trench TR. However, at the center portion of the semiconductor chip in the Y direction, the contact plug C2 is separated into two. The contact plug C2 reaches halfway a depth of the body layer PB that is a position deeper than a depth of the source region SR, and contacts with the source region SR. To reduce connection resistance of the contact plug C2 and the body layer PB, a p-type semiconductor region having a higher concentration than a concentration of the body layer PB may be formed in the semiconductor substrate SB1 between the contact plug C2 and the body layer PB. The source potential is supplied to the source region SR and the body layer PB via the source pad SP1 and the contact plug C2.

As shown in FIG. 3, a width in the short direction (X direction) of the trench TR gradually becomes small toward the lower surface side from the upper surface side of the semiconductor substrate SB1. In addition, a corner portion that is a boundary between the lower surface and the side surface of the trench TR is rounded. In a step of forming a structure of an inside of the trench TR, firstly, the insulation film IF3 is formed so as to be made comparatively thick and not to completely embed the inside of the trench TR. Next, the field plate electrode FG is formed in the trench TR and in a space between the insulation films IF3 covering the respective side surfaces on both sides of the trench TR in the short direction. Here, the upper surface of the field plate electrode FG is retreated backward from an upper end of the trench TR by performing etch back and the like. Subsequently, the upper surface of the insulation film IF3 is retreated backward from the upper surface of the field plate electrode FG by the etch back.

Subsequently, the insulation films IF1, IF2 are simultaneously formed, for example, by a thermal oxidation method. In addition, oxide film growth is performed by a Chemical Vapor Deposition (CVD) method as needed. Here, the insulation film IF1 covers the side surface of the trench TR, and the insulation film IF2 covers the field plate electrode FG exposed from the insulation film IF3. By utilizing characteristics (oxidation speeds are different by a plane orientation, an impurity concentration, and the like) of deposition by the thermal oxidation method, the thickness of the insulation film IF1 covering the side surface of the trench TR can be made smaller than the thickness of the insulation film IF2. Next, by embedding the gate electrode GE in the trench TR, the gate electrode GE, the field plate electrode FG, and the insulation films IF1, IF2, IF3 are formed.

Here, the field plate electrode FG has a convex portion that protrudes upward from the upper surface of the insulation film IF3 toward a gate electrode GE side at a center portion in the short direction of the trench TR in plan view. A part of the gate electrode GE sandwiches the convex portion in the short direction of the trench TR. That is, the gate electrode GE has a dent covering the upper end vicinity of the field plate electrode FG extending in the Z direction, and the upper end of the field plate electrode FG is fitted to the dent.

The insulation film IF1 insulates the source region SR, the drain region DR, and the body layer PB from the gate electrode GE. The minimum thickness of the insulation film IF1 between the semiconductor substrate SB1 and the gate electrode GE is T1. A value of the thickness T1 is, for example, 30 nm or more and 50 nm or less if the semiconductor device has a rated voltage (withstand voltage) of 40 V. The semiconductor device having the rated voltage of 40 V is a semiconductor device of a standard capable of safety maintaining an off state. In addition, the value of the thickness T1 is 70 nm or more and 90 nm or less if a semiconductor device has a rated voltage of 80 V. Each of the minimum thickness T2 of the insulation film IF2 and the minimum thickness of the insulation film IF3 is 250 nm or less.

A position where the thickness of the insulation film IF2 becomes minimum is such a location that the part of the gate electrode GE sandwiches the field plate electrode FG (convex portion) in the short direction of the trench, for example, like a location shown by T2 of FIG. 3. In other hands, between the side surface of the field plate electrode FG and the gate electrode GE opposing the side surface, the thickness of the insulation film IF2 becomes minimum. Therefore, in the first test and the second test described later, for example as insulation properties between the gate electrode GE and the field plate electrode FG, insulation properties of the insulation film IF2 between a side surface of the convex portion in the X direction and the gate electrode GE opposing the side surface are inspected. A position where the insulation film IF3 becomes minimum is a location between a lower end of the field plate electrode FG or a corner portion of the lower surface of the field plate electrode FG and a lower end of the trench TR or a corner portion of the lower surface of the trench TR, for example, like a location shown by T3 of FIG. 3. Therefore, in the second test described later, the insulation properties of the insulation film IF3 at such a location is inspected as the insulation properties between the drain region DR (semiconductor substrate SB1) and the field plate electrode FG.

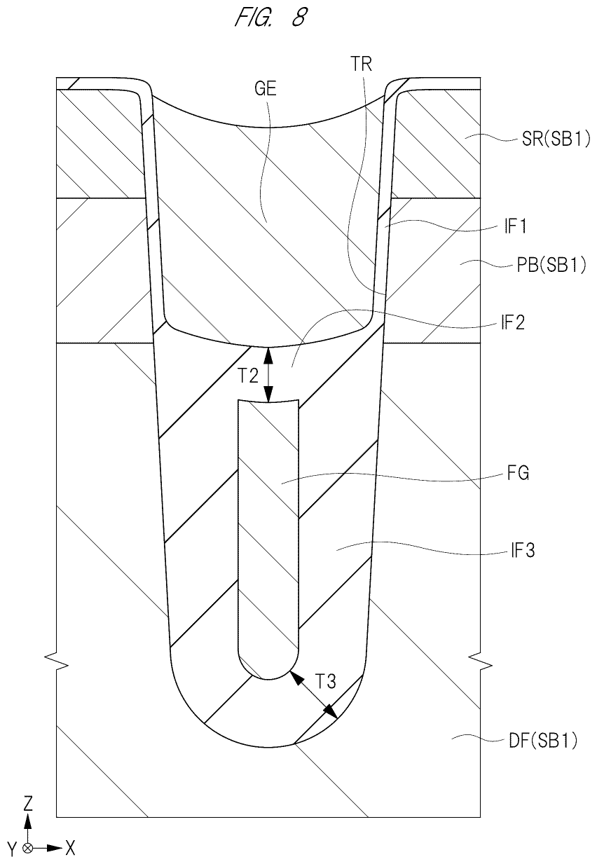

In FIG. 3, a structure in which an upper end (convex portion) of the field plate electrode FG is fitted into a concave portion of a bottom portion of the gate electrode GE is shown. However, each shape of the field plate electrode FG and the gate electrode GE is not limited to the structure shown by FIG. 3 and may have a structure, for example, as explained by using FIG. 8 later.

FIG. 4 is an equivalent circuit diagram showing the semiconductor device that is the present embodiment. A gate G, a source S, a drain D, and a field plate F that are nodes shown by FIG. 4 represent the gate electrode GE, the source electrode (source pad SP1, source region SR), the drain electrode DE (drain region DR), and the field plate electrode FG, respectively. The MOSFET 1Q has a built-in diode D1. An anode of the built-in diode D1 is connected to the source S, and a cathode of the built-in diode D1 is connected to the drain D. A resistance and a capacitance that are connected between the gate G and the field plate F in series represent the insulation film IF2. A resistance and a capacitance that are connected between the drain D and the field plate F in series represent the insulation film IF3. Here, the field plate F and the source S are electrically connected to each other by the bonding wire BW. However, the first inspection and the second inspection explained later are performed before the field plate F and the source S are electrically connected to each other by the bonding wire BW.

### First Inspection

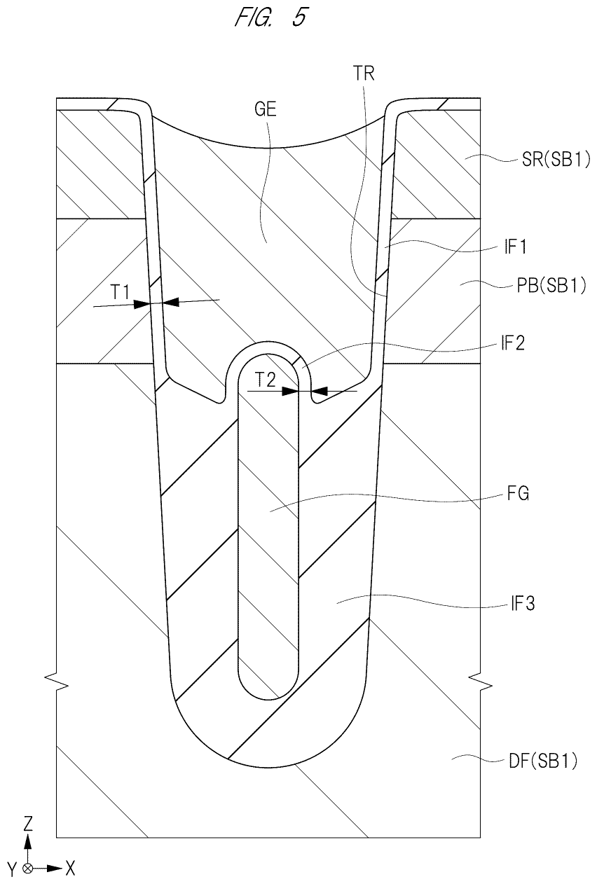

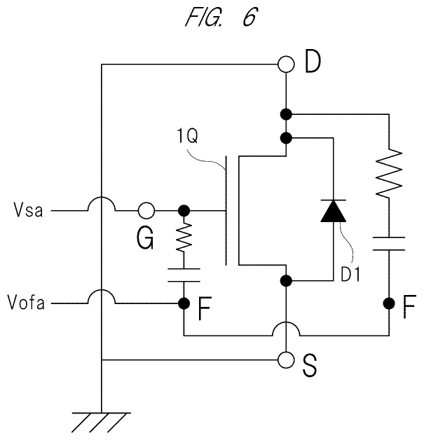

Next, the first inspection that is the screening test performed to the above semiconductor chip will be explained by using FIG. 5 and FIG. 6. The first inspection is an inspection performed when a case in which a difference between the thickness T1 of the insulation film IF1 and the thickness T2 of the insulation film IF2 as shown by FIG. 3 is small or a case in which the thickness T3 of the insulation film IF3 is much thicker than the thicknesses T1, T2 is supposed. For example, the thickness T3 of the insulation film IF3 is 1.5 times or more than the thickness T2 of the insulation film IF2. FIG. 5 is a cross-sectional view showing the semiconductor device that is the present embodiment. FIG. 6 is an equivalent circuit diagram showing the semiconductor device that is the present embodiment. In the first inspection, the insulation properties between the source region and the gate electrode and the insulation properties between the gate electrode and field plate electrode are simultaneously inspected. As such an inspection method, the following method will be used.

Here, the source S and the drain D are connected to a ground potential. Namely, the source electrode and the drain electrode are fixed to the ground potential. In addition, an offset voltage Vofa is applied to the field plate F (field plate electrode FG). Further, a screening voltage Vsa is applied to the gate G (gate electrode GE). Consequently, the insulation properties of the insulation film IF1 between the source region SR and the gate region GE and the insulation properties of the insulation film IF2 between the gate electrode GE and the field plate electrode FG are inspected.

In the first inspection, firstly, an object to apply the screening voltage Vsa, namely, an electrode to contact with a location (location to pay attention to) particularly requiring the inspection in the plurality of insulation films different from each other in thickness is determined. Here, the insulation film IF1 is paid attention to, and applying the screening voltage Vsa to the gate electrode GE contacting with the insulation film IF1 is determined. A value of the screening voltage Vsa is determined so that an electric field E applied to the insulation film to pay attention to is within a predetermined range. The predetermined range of the electric field E is, for example, 0.6 V/nm or more and 0.8 V/nm or less.

The value of the screening voltage Vsa is a value obtained by multiplying the electric field E applied to the insulation film IF1 and the minimum thickness T1 of the insulation film IF1. Namely, when the insulation film IF1 between the source region SR fixed to the ground potential (for example, 0 V) and the gate electrode GE is paid attention to, the screening voltage Vsa applied to the gate electrode GE can be calculated by Vsa=T1×E. As an example, when the minimum thickness of the insulation film IF1 is 50 nm, the screening voltage Vsa is 30 V or more and 40 V or less. In addition, when the minimum thickness of the insulation film IF1 is 80 nm, the screening voltage Vsa is 48 V or more and 64 V or less.

Next, an object to apply the offset voltage Vofa is determined. Namely, the insulation film to pay attention to next the insulation film IF1 in the first inspection in the plurality of insulation films different from each other in thickness is determined, and the electrode to contact with the above insulation film and to apply the offset voltage Vof is determined. Here, the insulation film IF2 is paid attention to, and applying the offset voltage Vofa to the field plate electrode FG contacting with the insulation film IF2 is determined. The value of the offset voltage Vofa is determined so that the electric field E applied to the insulation film to pay attention to is within the same predetermined range as that of the electric field E applied to the insulation film IF1. The predetermined range of the electric field E is, for example, 0.6 V/nm or more and 0.8 nm or less.

The value of the offset voltage Vofa is determined by a ratio of the minimum thickness T1 of the insulation film IF1 and the minimum thickness T2 of the insulation film IF2. Here, the value of the offset voltage Vofa is determined so as to satisfy the following Equation 1:

$$( Vsa - Vofa ) / T 2 = Vsa / T 1. \qquad ( Equation 1 )$$

The term (Vsa−Vofa) in Equation 1 represents a potential difference between two regions sandwiching the insulation IF2, namely, between the gate electrode GE and the field plate electrode FG. The term Vsa in Equation 1 represents a potential difference between two regions sandwiching the insulation film IF1, namely, between the source region SR fixed to the ground potential and the gate electrode GE. For example, when T1=50 nm, T2=100 nm, and Vsa=35 V, the offset voltage Vofa=−35 V is applied to the field plate electrode FG.

In the first inspection, by applying the screening voltage Vsa and the offset voltage Vofa so as to satisfy Equation 1, the same electric field is applied to each of the insulation films IF1, IF2. Namely, if the offset voltage is adjusted by considering the ratio of the thicknesses of the two insulation films IF1, IF2, the same electric field can be applied to the two insulation films IF1, IF2 different from each other in thickness. Consequently, the insulation properties can be simultaneously inspected to each of the insulation films IF1, IF2.

By the voltage of the screening voltage Vsa and the ratio of the thickness T1 and the thickness T2, whether the offset voltage Vofa becomes positive or negative is determined. Consequently, dielectric breakdown between the object to apply the offset voltage Vofa (here, field plate electrode FG) and the semiconductor substrate is SB1 prevented from occurring. In other words, decreasing the difference between the thickness T1 and the thickness T2 is important so as to satisfy Equation 1 and so that the dielectric breakdown between the object to apply the offset voltage Vofa and the semiconductor substrate SB1 does not occur.

### Second Inspection

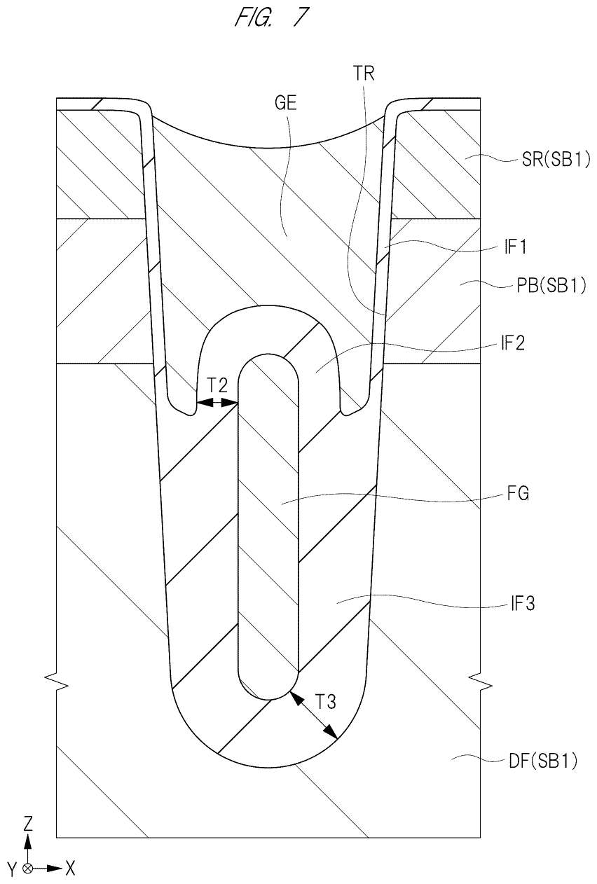

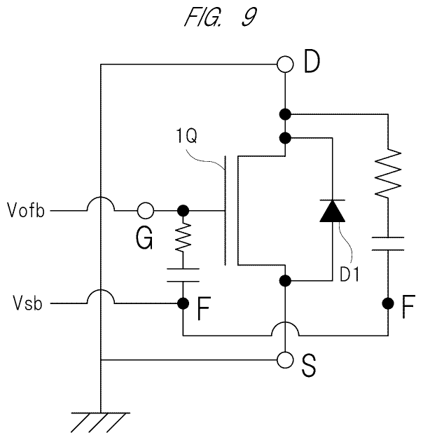

Next, the second inspection that is the screening inspection performed to the above semiconductor chip will be explained by using FIG. 7, FIG. 8, and FIG. 9. The second inspection is an inspection performed when a case in which a difference between the thickness 12 of the insulation film IF2 and the thickness T3 of the insulation film IF3 shown by FIG. 3 is small or a case in which the thickness T1 of the insulation film IF 1 is much thinner than the thickness T2 and the thickness T3 is supposed. The screening of the thin insulation film IF1 only may be performed before or after the second inspection. FIG. 7 and FIG. 8 are cross-sectional views showing the semiconductor device that is the present embodiment. FIG. 9 is an equivalent circuit diagram showing the semiconductor device that is the present embodiment.

The second inspection may be performed to any of the semiconductor devices shown by FIG. 7 and FIG. 8. A structure shown by FIG. 7 is a structure in which the convex portion of the upper end of the field plate electrode FG protrudes from above the upper surface of the insulation film IF3 similarly to the structure shown by FIG. 3 and in which a side surface of the convex portion and the part of the gate electrode GE oppose each other. However, in comparison with FIG. 3, the thickness T2 of the insulation film IF2 of FIG. 7 is large, and the difference between the thickness T2 of the insulation film IF2 and the thickness T3 of the insulation film IF3 is small.

A structure shown by FIG. 8 is different from the structure shown by FIG. 3 in that the field plate electrode FG does not have a portion protruding from above the upper surface of the insulation film IF3. Here, the bottom portion of the gate electrode GE has a gentle curved surface, and does not have a concave portion into which the upper end of the field plate electrode FG is fitted. Namely, the upper end of the field plate electrode FG is located under the lowermost surface of the gate electrode GE via the insulation film IF2. At this time, the minimum thickness T2 of the insulation film IF2 is equal to, for example, a distance between the gate electrode GE and the field plate electrode FG in the Z direction. In comparison with FIG. 3, the thickness T2 of the insulation film IF2 of FIG. 8 is large, and the difference between the thickness T2 of the insulation film IF2 and the thickness T3 of the insulation film IF3 is small.

In the second inspection, the insulation properties between the drain region and the field plate electrode, and the insulation properties between the gate electrode and the field plate electrode are simultaneously inspected. As such an inspection method, the following method is utilized.

Here, the source S and the drain D are connected to the ground potential. Namely, the source electrode and the drain electrode are fixed to the ground potential. In addition, the screening voltage Vsa is applied to the field plate F (field plate electrode FG). Further, an offset voltage Vofb is applied to the gate G (gate electrode GE). Consequently, the insulation properties of the insulation film IF3 between the drain electrode DR and the field plate electrode FG, and the insulation properties of the insulation film IF2 between the gate electrode GE and the above field plate electrode FG are inspected.

In the second inspection, firstly, an object to apply to a screening voltage Vsb, namely, an electrode contacting a location particularly requiring the inspection with (location to pay attention to) in the plurality of insulation films different from each other in film thickness is determined. Here, the insulation film IF3 is paid attention to, and applying the screening voltage Vsb to the field plate electrode FG contacting with the insulation film IF3 is determined. A value of the screening voltage Vsb is determined so that the electric field E applied to the object to pay attention to is within a predetermined range. The predetermined range of the electric field E is, for example, 0.6 V/nm or more and 0.8 nm/or less.

The value of the screening voltage Vsb is a value obtained by multiplying the electric field E applied to the insulation film IF3 and the minimum thickness T3 of the insulation film IF3. Namely, when the insulation film IF3 between the drain region DR fixed to the ground potential (for example, 0 V) and the field plate electrode FG is paid attention to, the screening voltage Vsb applied to the field plate electrode FG can be calculated by Vsb=T3×E. As an example, when the minimum thickness of the insulation film IF3 is 100 nm, the screening voltage Vsb is 60 V or more and 80 V or less.

Next, an object to apply to the offset voltage Vofb is determined. Namely, the insulation film to pay attention to next the insulation film IF3 in the second inspection in the plurality of insulation films different from each other in film thickness is determined, and the electrode to contact with such an insulation film and to apply the offset voltage Vofb is determined. Here, the insulation film IF2 is paid attention to, and applying the offset voltage Vofb to the gate electrode GE contacting with the insulation film IF2 is determined. The value of the offset voltage Vofb is determined so that the electric field E applied to the insulation film to pay attention to is within the same predetermined range as that of the electric field E applied to the insulation film IF3. The predetermined range of the electric field E is, for example, 0.6 V/nm or more and 0.8 V/nm or less.

The value of the offset voltage Vofb is determined by a ratio of the minimum thickness T3 of the insulation film IF3 and the minimum thickness T2 of the insulation film IF2. Here, the value of the offset voltage Vofb is determined so as to satisfy the following Equation 2:

$$( Vsb - Vofb ) / T 2 = Vsb / T 3. \qquad ( Equation 2 )$$

The term (Vsb−Vofb) in Equation 2 represents two regions sandwiching the insulation film IF2, namely, a potential difference between the gate electrode GE and the field plate electrode FG. The term Vsb in Equation 2 represents two regions sandwiching the insulation film IF3, namely, a potential difference between the drain region DR fixed to the ground potential and the field plate electrode FG. For example, when T3=100 nm, T2=75 nm, and Vsb=70 V, the offset voltage Vofb=17.5 V is applied to the gate electrode GE. In addition, when the semiconductor device has a rated voltage of 40 V, the offset voltage Vofb is, for example, −20 V or more and 20 V or less.

In the second inspection, by applying the screening voltage Vsb and the offset voltage Vofb so as to satisfy Equation 2, the same electric field E is applied to each of the insulation films IF2, IF3. Consequently, the insulation properties can be simultaneously inspected to the each of the insulation films IF2, IF3.

By the value of the screening voltage Vsb and the ratio of the thickness T3 and the thickness T2, whether the offset voltage Vofb becomes a positive or negative voltage is determined. Consequently, the insulation breakdown between the object to apply the offset voltage Vofb (here, gate electrode GE) and the semiconductor substrate SB1 is prevented from occurring. In other words, the decreasing the difference between the thickness T2 and the thickness T3 is important so as to satisfy Equation 2 and so that the insulation breakdown between the object to apply the offset voltage Vofb and the semiconductor substrate SB1 does not occur.

### Effects of Present Embodiment

In a deposition step of the insulation film (oxide film) in the manufacturing process of the semiconductor device, defects may be generated in the insulation films by occurring of dust, scratches, dirt, or the like. The insulation film at a location where the defects (deposition failures) occur may be locally thin in comparison with a portion at which no defect occurs in the insulation film. A product including the semiconductor device having the above defects in the insulation film may lead to breakdown in a comparatively short time. Therefore, by performing the inspection in advance, a method of eliminating the semiconductor device (product) early reaching end of lifetime due to the defects is adopted. In the inspection, the strong voltage is applied to the electrode of the semiconductor device. As a result, the semiconductor device having short lifetime (TDDB lifetime) causes the insulation breakdown then and there, thus making it possible to detect abnormality. Accordingly, shipment of the product having the defects is prevented.

In the inspection, it is conceivable to pay attention to the insulation film particularly easily causing the deposition failure and to apply the high electric field only to the above insulation film. The insulation film particularly easily causing the deposition failure is, for example, an insulation film that is formed between the gate semiconductor electrode and substrate and that is particularly thinner than the other insulation films. However, in the in-trench double-gate type power MOSFET, the plurality of insulation films contacting with the trench gate electrode including the gate electrode and the field plate electrode have different thicknesses, respectively. At this case, even in not only the thinnest insulation film but also the other insulation films, the failure in which the thickness of the insulation film becomes small may be caused due to occurrence of foreign matters during the manufacturing process and the like.

With respect to the in-trench double-gate type power MOSFET shown by FIG. 4, one method for performing the inspection by paying attention only to the insulation film having the minimum thickness is the following method. Namely, in the inspection, it is conceivable to fix the source S, the drain D, and the field plate F to the ground potential and to apply the screening voltage of, for example, about 35 V to the gate G. At this case, to the insulation film IF1 having the minimum thickness among the respective insulation films shown by FIG. 3, the high electric field is applied between the gate electrode GE and the semiconductor substrate SB1 (source region SR). As a result, when the thickness of the insulation film IF1 decreases due to the occurrence of the defects, the insulation breakdown is generated, so that the failure of the semiconductor device can be detected. However, the presence or absence of the defects of the other insulation films IF2, IF3 cannot be inspected at this case. For example, if the thickness of the insulation film IF1 designed at 50 nm and to be deposited is 30 nm due the defects, those defects can be detected by the above inspection. However, even if the thickness of the insulation film IF2 designed at 100 nm and to be deposited is 60 nm due the defects, those defects cannot be detected by the above inspection.

In addition, with respect to the in-trench double-gate type power MOSFET, another method for performing the inspection by paying attention only to the insulation film having the minimum thickness is the following method. Namely, in the inspection, it is conceivable to fix the gate G, the source S, and the drain to the ground potential and to apply the screening voltage of, for example, about 70 V to the field plate F. At this case, to the insulation film IF2 thinner in thickness than the insulation film IF3, the high electric field is applied between the gate electrode GE and the field plate electrode FG. As a result, when the thickness of the insulation film IF2 decreases due to the occurrence of the defects, the insulation breakdown is generated, so that the failure of the semiconductor device can be detected. However, the presence or absence of the defects of the other insulation films IF1, IF3 cannot be detected at this case.

As described above, even when the insulation film has the second or third largest thickness in design in the insulation films contacting with the trench gate electrode, the occurrence of the defects becomes a factor of causing a shortage of the lifetime of the semiconductor device. Accordingly, in the semiconductor device in which the insulation film insulating the electrode has the plurality of types of thicknesses, it is important to ensure the higher reliability by inspecting not only the insulation film at one location but also the insulation film having another film thickness. However, performing the separate inspections to each of the insulation films different from each other in thickness leads to complicated steps, and causes the increase in the manufacturing costs of the semiconductor device.

Therefore, in the present embodiment, by selecting two out of the insulation films at three locations, the two insulation films are simultaneously inspected by the one-time inspection. As such a method, by applying the same electric field to each of the two insulation films in the inspection, the insulation properties of the two insulation films can be inspected. Even if the thicknesses of the two insulation films to be inspected are different, as explained by using Equation 1 or Equation 2, by considering the ratio of the thicknesses of the two insulation films to adjust the offset voltage, the same electric field can be applied to each of the two insulation films.

As described above, in the present embodiment, the semiconductor device in which the insulation film insulating the electrodes has the plurality of types of thicknesses can simultaneously perform the inspection to two or more insulation films by the one-time inspection. Therefore, since the reliability of the plurality of types of insulation films can be ensured, the reliability of the semiconductor device can be improved. In addition, the number of times of the inspections can be prevented from increasing, and the manufacturing costs of the semiconductor device can be reduced.

In the present embodiment, performing the first inspection and the second inspection has been explained. For example, by performing the first inspection when the insulation film IF3 is further thicker than the insulation films IF2, IF3, the inspection can be simultaneously performed to the two insulation films IF1, IF2 having the small thickness among the insulation films that are formed in the trench and that have the plurality of types of thicknesses. In addition, for example, by performing the second inspection when the insulation film IF1 is further thinner than the insulation films IF2, IF3, the inspection can be simultaneously performed to the two insulation films IF2, IF3 having the large thickness among the insulation films that are formed in the trench and that have the plurality of types of thicknesses. Accordingly, since the inspections at the plurality of locations can be performed by the one-time inspection, the reliability of the 5 semiconductor device can be improved.

As described above, the invention made by the present inventor have been specifically explained based on the embodiments, but the present invention is not limited to the above embodiments and, needless to say, can be variously 10 modified within a range not departing from the gist thereof.

For example, polarities of componential portions of the MOSFET described in the above embodiments may be replaced. Namely, the MOSFET may be a p-type MOSFET.

1. A method for inspecting a semiconductor device, the semiconductor device comprising:
a semiconductor substrate having a first main surface and a second main surface opposite the first main surface;
a source region formed on a side of the first main surface in the semiconductor substrate;
a drain region formed on a side of the second main surface in the semiconductor substrate;
a trench penetrating through the source region and formed so as to reach a predetermined depth toward the second main surface from the first main surface;
a gate electrode formed in the trench and electrically insulated from the source region and the drain region;
a field plate electrode formed on the side of the second main surface with respect to the gate electrode and electrically insulated from the source region, the drain region, and the gate electrode in the trench;
a source electrode electrically connected to the source region; and
a drain electrode electrically connected to the drain region,
wherein a first inspection includes:
fixing the source electrode and the drain electrode to a ground potential;
applying a first offset voltage to the field plate electrode;
applying a first screening voltage to the gate electrode; and
thereby inspecting insulation properties between the source region and the gate electrode and insulation properties between the gate electrode and the field plate electrode.

2. A method for inspecting a semiconductor device, the semiconductor device comprising:
a semiconductor substrate having a first main surface and a second main surface opposite the first main surface;
a source region formed on a side of the first main surface in the semiconductor substrate;
a drain region formed on a side of the second main surface in the semiconductor substrate;
a trench penetrating through the source region and formed so as to reach a predetermining depth toward the second main surface from the first main surface;
a gate electrode formed in the trench and electrically insulated from the source region and the drain region;
a field plate electrode formed the side of the second main surface with respect to the gate electrode and electrically insulated from the source region, the drain region, and the gate electrode in the trench;
a source electrode electrically connected to the source region; and
a drain region electrically connected to the drain region,
wherein a second inspection includes:
fixing the source electrode and the drain electrode to a ground potential;
applying a second offset voltage to the gate electrode;
applying a second screening voltage to the field plate electrode; and
thereby inspecting insulation properties between the drain region and the field plate electrode and insulation properties between the gate electrode and the field plate electrode.

3. The method according to claim 1,
wherein the semiconductor device further comprises:
a first insulation film formed between the source region and the gate electrode; and
a second insulation film formed between the gate electrode and the field plate electrode,
wherein in the first inspection, an electric field applied to each of the first insulation film and the second insulation film is 0.6 V/nm or more and 0.8 V/nm or less.

4. The method according to claim 2,
wherein the semiconductor device further comprises:
a second insulation film formed between the gate electrode and the field plate electrode; and
a third insulation film formed between the drain electrode and the field plate electrode,
wherein in the second inspection, an electric filed applied to each of the second insulation film and the third insulation film is 0.6 V/nm or more and 0.8 V/nm or less.

5. The method according to claim 3,
wherein a value of the first screening voltage is a value obtained by multiplying an electric field applied to the first insulation film and a minimum thickness of the first insulation film.

6. The method according to claim 4,
wherein a value of the second screening voltage is a value obtained by multiplying an electric field applied to the third insulation film and a minimum thickness of the third insulation film.

7. The method according to claim 1,
wherein the semiconductor device further comprises:
a first insulation film formed between the source region and the gate electrode; and
a second insulation film formed between the gate electrode and field plate electrode,
wherein when the first screening voltage is Vsa, the first offset voltage is Vofa, a minimum thickness of the first insulation film is T1, and a minimum thickness of the second insulation film is T2, they satisfy (Vsa−Vofa)/T2=Vsa/T1.

8. The method according to claim 2,
wherein the semiconductor device further comprises:
a second insulation film formed between the gate electrode and the field plate electrode; and
a third insulation film formed between the drain electrode and the field plate electrode,
wherein when the second screening voltage is Vsb, the second offset voltage Vofb, a minimum thickness of the third insulation film is T3, and a minimum thickness of the second insulation film is T2, they satisfy (Vsb−Vofb)/T2=Vsb/T3.

9. The method according to claim 1,
wherein insulation properties between the source region and the gate electrode and insulation properties between the gate electrode and the field plate electrode are simultaneously inspected.

10. The method according to claim 2,
wherein insulation properties between the drain region and the gate electrode and insulation properties between the gate electrode and the field plate electrode are simultaneously inspected.

11. The method according to claim 1,
wherein the semiconductor device further comprises a first insulation film formed between the source region and the gate electrode, and
wherein when a minimum thickness of the first insulation film is 50 nm, the first screening voltage is 30 V or more and 40 V or less.

12. The method according to claim 1,
wherein the semiconductor device further comprises a first insulation film formed between the source region and the gate electrode, and
wherein when a minimum thickness of the first insulation film is 80 nm, the first screening voltage is 48 V or more and 64 V or less.

13. The method according to claim 2,
wherein the semiconductor device further comprises a third insulation film formed between the drain region and the field plate electrode, and
wherein when a minimum thickness of the third insulation film is 100 nm, the second screening voltage is 60 V or more and 80 V or less.

14. The method according to claim 1,
wherein the semiconductor device further comprises a second insulation film formed between the gate electrode and the field plate electrode,
wherein the trench extends along the first main surface,
wherein the field plate electrode has a convex portion toward a side of the gate electrode at a center portion in a short direction of the trench in plan view,
wherein a part of the gate electrode sandwiches the convex portion in the short direction of the trench, and
wherein in the first inspection, as insulation properties between the gate electrode and the field plate electrode, insulation properties of the second insulation film between a side surface of the convex portion in the short direction and the gate electrode opposing the side surface of the convex portion are inspected.

15. The method according to claim 2,
wherein the semiconductor device further comprises a second insulation film formed between the gate electrode and the field plate electrode,
wherein the trench extends along the first main surface,
wherein the field plate electrode has a convex portion toward a side of the gate electrode at a center portion in a short direction of the trench in plan view,
wherein a part of the gate electrode sandwiches the convex portion in the short direction of the trench, and
wherein in the second inspection, as insulation properties between the gate electrode and the field plate electrode, insulation properties of the second insulation film between a side surface of the convex portion in the short direction and the gate electrode opposing the side surface of the convex portion are inspected.

16. The method according to claim 1,
wherein the semiconductor device further comprises:
a first insulation film formed between the source region and the gate electrode;
a second insulation film formed between the gate electrode and the field plate electrode; and
a third insulation film formed between the drain region and the field plate electrode,
wherein a thickness of the first insulation film is 30 nm or more and 50 nm or less, or 70 nm or more and 90 nm or less, and
wherein a thickness of the third insulation film is 1.5 times or more than a thickness of the second insulation film.

17. The method according to claim 1,
wherein the semiconductor device further comprises:
a first insulation film formed between the source region and the gate electrode;
a second insulation film formed between the gate electrode and the field plate electrode; and
a third insulation film formed between the drain region and the field plate electrode,
wherein each of the first insulation film, the second insulation film, and the third insulation film is an oxide silicon film, and
wherein each of the gate electrode and the field plate electrode is made of a polycrystalline silicon film.

18. The method according to claim 1,
wherein the gate electrode, the source region, and the drain region configure a MOS Field Effect Transistor.

19. The method according to claim 1,
wherein the semiconductor device further comprises an interlayer insulation film formed on the first main surface, the gate electrode, and the source region, and
wherein the gate electrode and the source electrode are electrically insulated to each other by the interlayer insulation film.

20. The method according to claim 2,
wherein the second offset voltage is −20 V or more and 20 V or less.
